(19) United States
(12) Patent Application Publication
(10) Pub. No.: US 2023/0178429 A1
(43) Pub. Date: Jun. 8, 2023

(54) ACCURATE METAL LINE AND VIA HEIGHT CONTROL FOR TOP VIA PROCESS

(71) Applicant: INTERNATIONAL BUSINESS MACHINES CORPORATION, Armonk, NY (US)

(72) Inventors: TSUNG-SHENG KANG, Ballston Lake, NY (US); RUILONG XIE, Niskayuna, NY (US); TAO LI, Slingerlands, NY (US); CHIH-CHAO YANG, Glenmont, NY (US)

(21) Appl. No.: 17/643,408

(22) Filed: Dec. 8, 2021

(51) Int. Cl. H01L 21/768; H01L 23/522; H01L 23/528; H01L 23/532; H01L 21/3213

(52) U.S. Cl. CPC H01L 21/76879; H01L 21/32136; H01L 21/32139; H01L 21/76837; H01L 21/76852; H01L 21/76885; H01L 23/5226; H01L 23/5283; H01L 23/53252

(57) ABSTRACT

A method of manufacturing an interconnect structure for a semiconductor device is provided. The method includes forming a metal interconnect layer on a substrate. The method includes forming a hardmask on the metal interconnect layer, patterning the metal interconnect layer and hardmask, forming a sacrificial material layer to overfill the patterned metal interconnect layer and hardmask, and selectively removing a portion of the sacrificial layer and the hardmask to form a via opening. The method also includes forming a via on the metal interconnect layer in the via opening by a selective metal growth process.

### BACKGROUND

The present disclosure relates to metal interconnect structures for semiconductor devices. In particular, the present disclosure related to top vias for interconnect structures. In integrated circuits (ICs), interconnects are structures that connect two or more circuit elements (such as transistors) together electrically. The design and layout of interconnects on an IC may be a factor affecting its proper function, performance, power efficiency, reliability, and fabrication yield. ICs with complex circuits may require multiple levels of interconnect to form circuits that have minimal area. For example, complex ICs may have over 15 layers of interconnect. Each level of interconnect is separated from each other by a layer of dielectric. To make vertical electrical connections between interconnects on different levels, vias are used. It may be desirable to maintain a uniform height for metal lines on an interconnect layer, and it may also be desirable to maintain a uniform height and shape of the top via structures that are formed on the metal line.

### SUMMARY

Embodiments of the present disclosure relate to a method of manufacturing an interconnect structure for a semiconductor device. The method includes forming a metal interconnect layer on a substrate. The method includes forming a hardmask on the metal interconnect layer, patterning the metal interconnect layer and hardmask, forming a sacrificial material layer to overfill the patterned metal interconnect layer and hardmask, and selectively removing a portion of the sacrificial layer and the hardmask to form a via opening. The method also includes forming a via on the metal interconnect layer in the via opening by a selective metal growth process.

Embodiments of the present disclosure relate to an interconnect structure. The interconnect structure includes a metal interconnect layer formed on a substrate, a via formed on the metal interconnect layer by a selective metal growth process. The via has a positive taper angle or is vertical in a first direction in a cross-sectional view, and the via has a negative or vertical taper angle in a second direction in the cross-sectional view that is orthogonal to the first direction.

The above summary is not intended to describe each illustrated embodiment or every implementation of the present disclosure.

### BRIEF DESCRIPTION OF THE DRAWINGS

The drawings included in the present application are incorporated into, and form part of the specification. They illustrate embodiments of the present disclosure and, along with the description, explain the principles of the disclosure. The drawings are only illustrative of certain embodiments and do not limit the disclosure.

FIG. 1A is a cross-sectional view of an interconnect structure of the semiconductor device of FIG. 1B taken along line X, that includes a metal line and a top via at an intermediate stage of the manufacturing process, according to embodiments.

FIG. 1B is a top-down view of an interconnect structure of a semiconductor device at an intermediate stage of the manufacturing process, according to embodiments.

FIG. 1C is a cross-sectional view of the interconnect structure of the semiconductor device of FIG. 1B taken along line Y, that includes a metal line and a top via at an intermediate stage of the manufacturing process, according to embodiments.

FIG. 2A is a cross-sectional view of the interconnect structure of the semiconductor device of FIG. 1A, after additional fabrication operations, according to embodiments.

FIG. 2B is a cross-sectional view of the interconnect structure of the semiconductor device of FIG. 1C, after additional fabrication operations, according to embodiments.

FIG. 3A is a cross-sectional view of the interconnect structure of the semiconductor device of FIG. 2A, after additional fabrication operations, according to embodiments.

FIG. 3B is a cross-sectional view of the interconnect structure of the semiconductor device of FIG. 2C, after additional fabrication operations, according to embodiments.

FIG. 4A is a cross-sectional view of the interconnect structure of the semiconductor device of FIG. 3A, after additional fabrication operations, according to embodiments.

FIG. 4B is a cross-sectional view of the interconnect structure of the semiconductor device of FIG. 3C, after additional fabrication operations, according to embodiments.

FIG. 5A is a cross-sectional view of the interconnect structure of the semiconductor device of FIG. 4A, after additional fabrication operations, according to embodiments.

FIG. 5B is a cross-sectional view of the interconnect structure of the semiconductor device of FIG. 4C, after additional fabrication operations, according to embodiments.

FIG. 6A is a cross-sectional view of the interconnect structure of the semiconductor device of FIG. 5A, after additional fabrication operations, according to embodiments.

FIG. 6B is a cross-sectional view of the interconnect structure of the semiconductor device of FIG. 5C, after additional fabrication operations, according to embodiments.

FIG. 7A is a cross-sectional view of the interconnect structure of the semiconductor device of FIG. 6A, after additional fabrication operations, according to embodiments.

FIG. 7B is a cross-sectional view of the interconnect structure of the semiconductor device of FIG. 6C, after additional fabrication operations, according to embodiments.

FIG. 8A is a cross-sectional view of the interconnect structure of the semiconductor device of FIG. 7A, after additional fabrication operations, according to embodiments.

FIG. 8B is a cross-sectional view of the interconnect structure of the semiconductor device of FIG. 7C, after additional fabrication operations, according to embodiments.

FIG. 9A is a cross-sectional view of the interconnect structure of the semiconductor device of FIG. 8A, after additional fabrication operations, according to embodiments.

FIG. 9B is a cross-sectional view of the interconnect structure of the semiconductor device of FIG. 8C, after additional fabrication operations, according to embodiments.

### DETAILED DESCRIPTION

The present disclosure relates to interconnect structures for semiconductor devices. In particular, the present disclosure related to top vias formed over metal lines of interconnect structures.

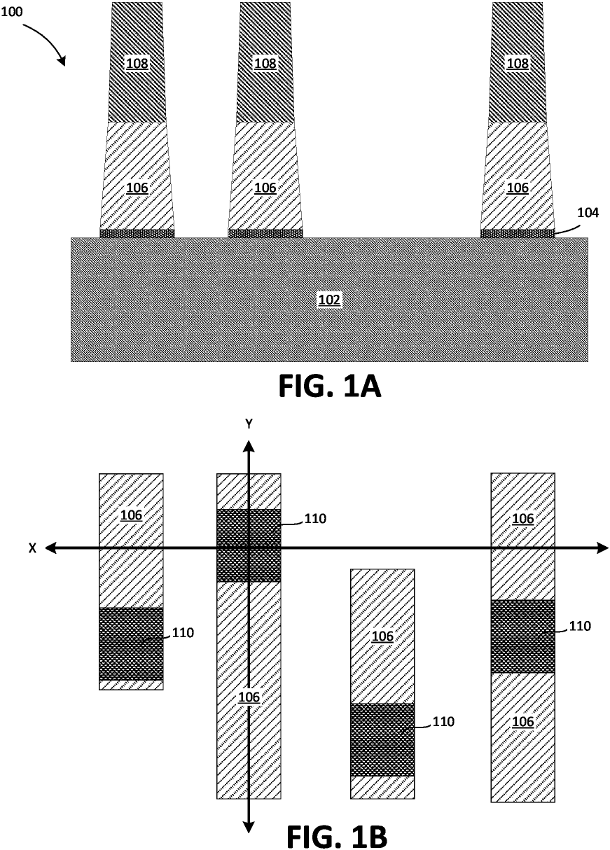

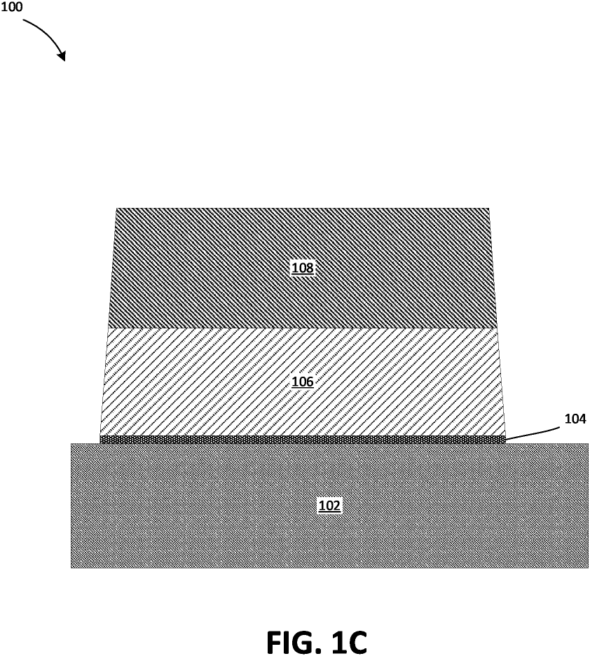

In certain embodiments, the top vias are formed over metal lines, where no sidewall metal liner is present for both the metal lines and the vias. In certain embodiments, the top vias have a negative taper profile (or straight profile or vertical profile) in a cross-metal line direction (i.e., the X line direction of FIG. 1B), and have a positive taper profile in an along-metal line direction (i.e., the Y line direction of FIG. 1B).

In certain embodiments, a method of forming an interconnect structure includes forming metal lines with hard mask with subtractive metal patterning, forming sacrificial material to overfill the metal lines and hardmasks, selectively etching the hardmasks where vias are going to be formed, selective metal growth to form top vias, removing sacrificial materials and hardmasks, and forming low-k dielectric to overfill said metal lines and vias.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) are between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography.

Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film’s electrical and mechanical properties.

Removal/etching is any process that removes material from the wafer. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material.

Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, generally, integrated circuits include a complex network of conductive interconnects fabricated on a semiconductor substrate in which semiconductor devices have been formed. Efficient routing of these interconnects requires formation of multilevel or multilayered schemes, such as, for example, single or dual damascene wiring structures.

Within an interconnect structure, conductive vias run perpendicular to the semiconductor substrate and conductive lines run parallel to the semiconductor substrate. According to conventional damascene processing, lines and vias are created within a dielectric layer. A dielectric layer is patterned to create grooves which become lines and holes which become vias. Metal is deposited on the patterned surface such as by electroplating to fill the grooves and holes. Excess is removed, such as by CMP, thereby forming lines along the top of a given dielectric layer, and forming vias which extend below the lines in order to connect to an underlying layer.

Referring now to the drawings in which like numerals represent the same or similar elements and initially to FIG. 1A, an exemplary method of manufacturing a top via on a metal line interconnect for a semiconductor device 100 to which the present embodiments may be applied is shown, where FIG. 1A is a cross-sectional view of the top view of FIG. 1B taken along line X. As shown in FIG. 1A, an underneath device 102 (or substrate) is provided as a base layer upon which the various metal lines and vias are formed. It should be appreciated that the underneath device 102 could be a substrate or any other suitable device. Underneath device 102 may comprise a semiconducting material, a conductive material or any combination thereof. When the underneath device 102 comprises a semiconducting material, any semiconductor such as Si, SiGe, SiGeC, SiC, Ge alloys, GaAs, InAs, InP and other III/V or II/VI compound semiconductors may be used. In addition to these listed types of semiconducting materials, the present disclosure also contemplates cases in which the underneath device 102 is a layered semiconductor such as, for example, Si/SiGe, Si/SiC, silicon-on-insulators (SOIs) or silicon germanium-on-insulators (SGOIs). When the underneath device 102 comprises a semiconducting material, one or more semiconductor devices such as, for example, complementary metal oxide semiconductor (CMOS) devices can be fabricated thereon. When underneath device 102 is a conducting material, the substrate may include, for example, polySi, an elemental metal, alloys of elemental metals, a metal silicide, a metal nitride or combinations thereof including multilayers. Further, the underneath device 102 can be single crystalline, polycrystalline, amorphous, or have a combination of at least two of a single crystalline portion, a polycrystalline portion, and an amorphous portion.

As shown in FIG. 1A, a metal liner layer 104 is formed on the underneath device 102. The metal liner layer 104 may include, for example, TaN or any other suitable material. A bulk metal layer 106 (or metal layer or metal interconnect layer) is formed on the metal liner layer 104. The bulk metal layer 106 may be composed of, for example, Ru. However, it should be appreciated that the bulk metal layer 106 may be composed of one or more materials other than Ru. For example, bulk metal layer 106 is conductive and can be a refractory metal or any metal that can be dry etched including but not limited to Al, Cr, Cu, Co, Ni, Hf, Ir, Mo, Nb, Os, Re, Rh, Ru, Ta, Ti, W, V, Zr, and alloys thereof. A hardmask 108 layer is formed on the bulk metal layer 106. The bulk metal layer 106, the hardmask 108 and the metal liner layer 104 can be deposited and patterned by a subtractive metal etching process to form the structures shown in FIG. 1A.

Referring now to FIG. 1B, this figure is a top-down view of the semiconductor device 100 of FIG. 1A. FIG. 1B shows one example pattern for metal interconnects including the bulk metal layer 106 and the locations of the top vias (generically shown as top via 110). However, it should be appreciated that any suitable pattern, number and/or arrangement of bulk metal layers 106 and top vias 110 may be used. FIG. 1C is a cross-sectional view of the top view of FIG. 1B taken along line Y.

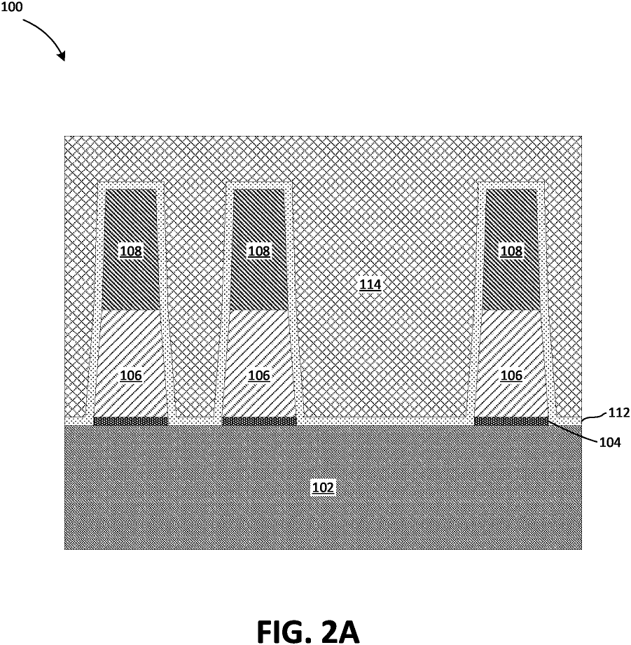

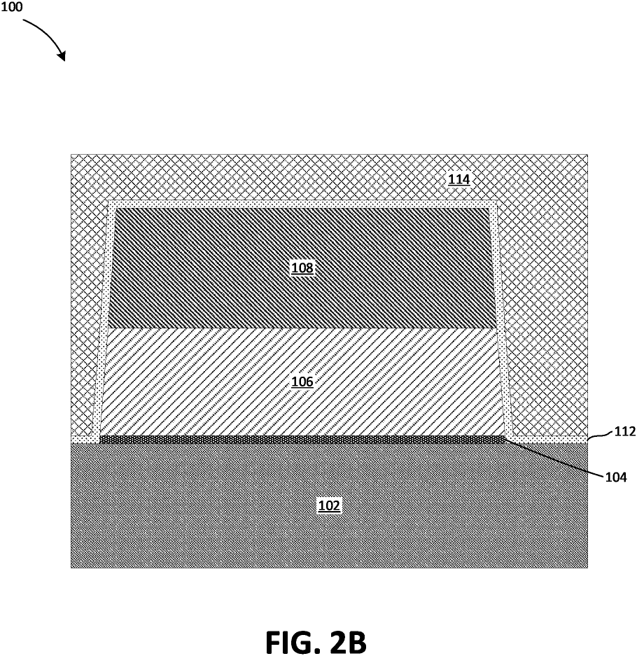

Referring now to FIG. 2A, this figure is a cross-sectional view of the interconnect structure of the semiconductor device 100 of FIG. 1A, after additional fabrication operations, according to embodiments. As shown in FIG. 2A and FIG. 2B (a cross-sectional view of the interconnect structure of the semiconductor device of FIG. 1B, after additional fabrication operations), a liner layer 112 (e.g., SiN) is formed over the entire semiconductor device 100 (i.e., including the sidewalls of the bulk metal layer 106 and the hardmask 108). The liner layer 112 may be formed by chemical vapor deposition (CVD), plasma-enhanced chemical vapor deposition (PECVD), or any other suitable material deposition process. As also shown in FIG. 2A, a sacrificial material layer 114 is formed over the liner layer 112 and is formed to a sufficient thickness to fill in the spaces between the different bulk metal layers 106 and hardmasks 108 and to a height that is at or above an upper surface of the liner layer 112. In certain examples, the sacrificial material layer 114 may be etched back and/or subjected to a CMP process to planarize the layer.

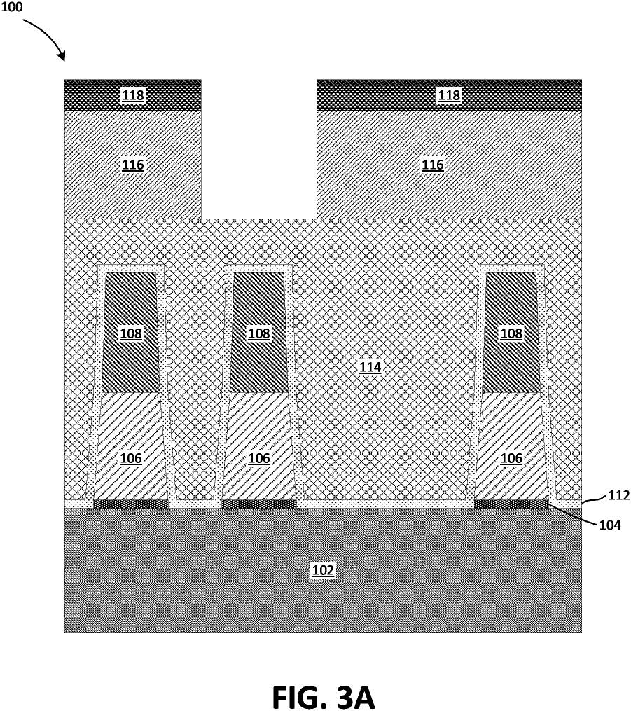

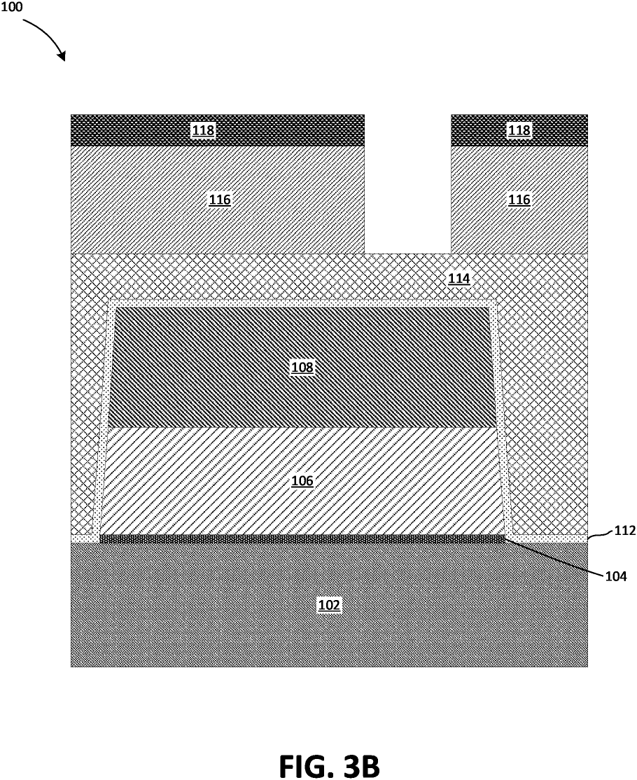

Referring now to FIG. 3A, this figure is a cross-sectional view of the interconnect structure of the semiconductor device 100 of FIG. 2A, after additional fabrication operations, according to embodiments. As shown in FIG. 3A, an organic planarization (OPL) layer 116 is formed over the semiconductor device 100. Then, a silicon containing Anti-Reflective Coating (SiARC) layer 118 (or metal cap layer) is formed over the OPL layer 116. Then, an OPL open process is performed to pattern the OPL layer 116 and the SiARC layer 118 to result in the structures shown in FIGS. 3A and 3B (a cross-sectional view of the interconnect structure of the semiconductor device 100 of FIG. 2B, after additional fabrication operations).

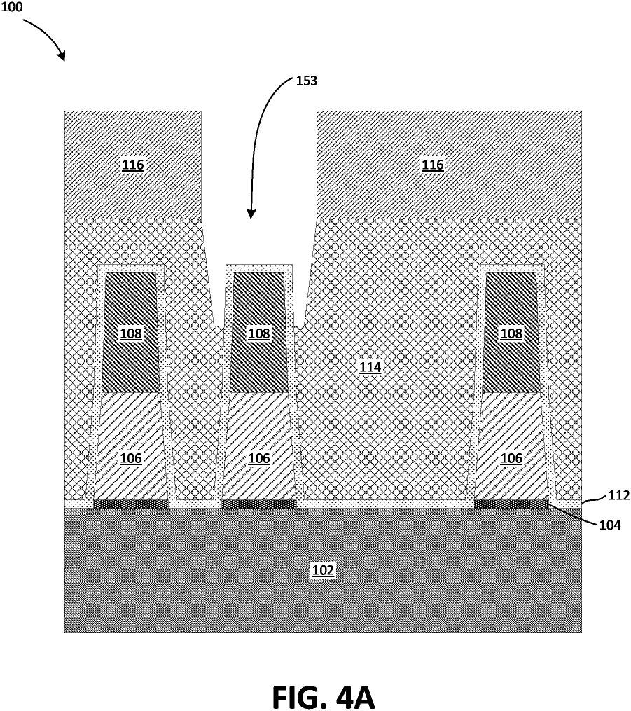

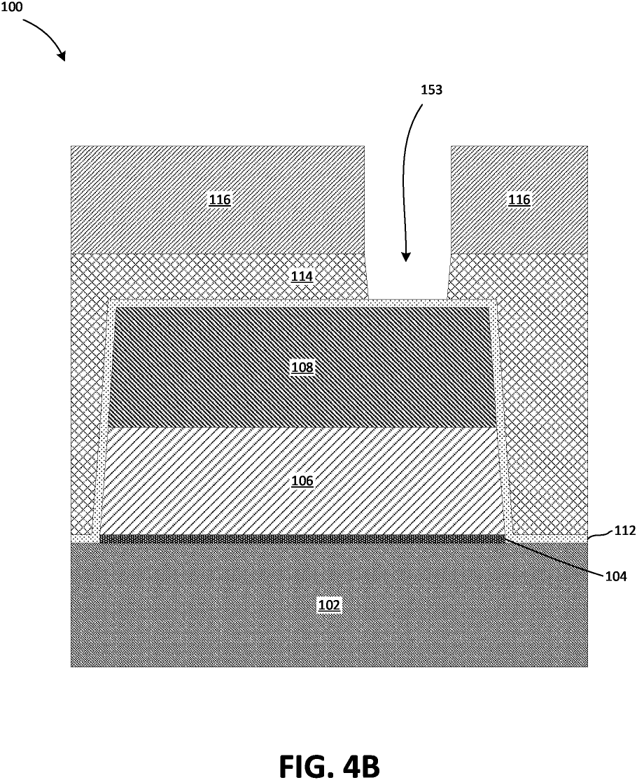

Referring now to FIG. 4A, this figure is a cross-sectional view of the interconnect structure of the semiconductor device 100 of FIG. 3A, after additional fabrication operations, according to embodiments. As shown in FIGS. 4A and 4B (a cross-sectional view of the interconnect structure of the semiconductor device 100 of FIG. 3B, after additional fabrication operations), an etching operation is performed to remove the SiARC layer 118 and portions of the sacrificial material layer 114 to reveal portions of the hardmask 108 (i.e., as shown in FIGS. 4A and 4B, the liner layer 112 still covers the hardmask 108 at this stage of the manufacturing process). As shown in FIG. 4A, the sacrificial material layer 114 is removed to a level that is below an upper surface of the hardmask 108. Also, in this example shown in FIG. 4A, the opening 153 (or via opening) formed by the removal of the sacrificial material layer 114 is wider than a width of an upper portion of the hardmask 108 so that at least a portion of the sidewalls of the hardmask 108 are exposed down to the depth of the opening 153. As shown in FIG. 4B, the opening 153 only goes down to a depth of an upper surface of the liner layer 112.

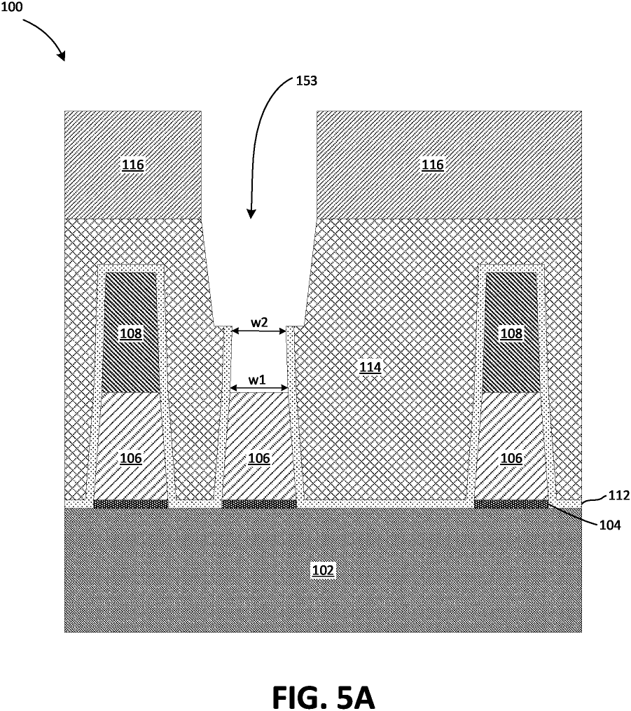

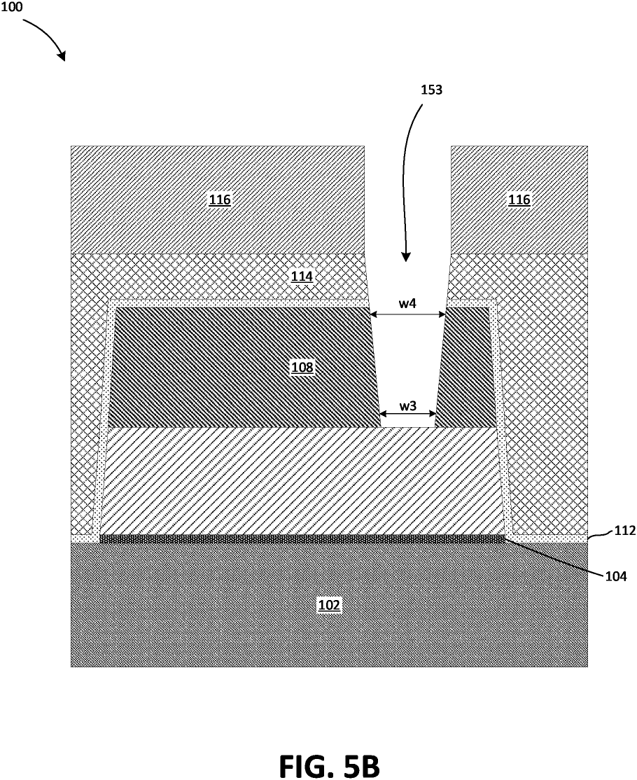

Referring now to FIG. 5A, this figure is a cross-sectional view of the interconnect structure of the semiconductor device 100 of FIG. 4A, after additional fabrication operations, according to embodiments. As shown in FIGS. 5A and 5B (a cross-sectional view of the interconnect structure of the semiconductor device 100 of FIG. 4B, after additional fabrication operations), a selective reactive ion etching (RIE) process is performed to remove the liner layer 112 in the openings 153. Also, the hardmask 108 is also removed during the RIE process. It should be notes that the location where the hardmask 108 is removed is at the intersection of lines X and Y in FIG. 1B. Thus, it can be seen in FIG. 5A that the area where the hardmask 108 is removed leaves a negative taper (or straight taper) in the exposed space above the bulk metal layer 106. In other words, the space above the bulk metal layer 106 in FIG. 5A has a first width w1 that is ≥ w2. This will allow for the subsequently formed via to have a negative taper when viewed in cross-section along the X line of FIG. 1B. Moreover, it can be seen in FIG. 5B that the area where the hardmask 108 is removed leaves a positive taper in the exposed space above the bulk metal layer 106. In other words, the space above the bulk metal layer 106 in FIG. 5B has a third width w3 that is ≤ w4. This will allow for the subsequently formed via to have a negative taper when viewed in cross-section along the Y line of FIG. 1B. As such, in certain embodiments, the taper angle of the opening is different (i.e., negative versus positive or straight versus positive) in the X and Y directions indicated in FIG. 1B.

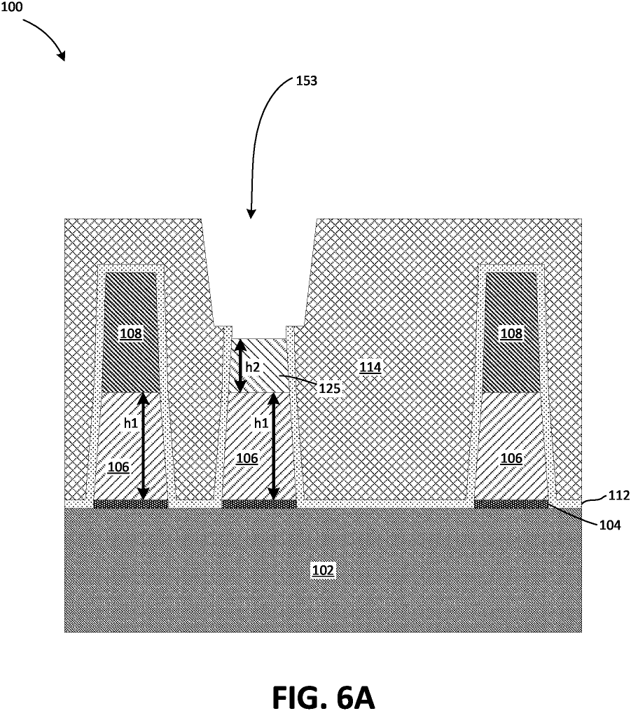

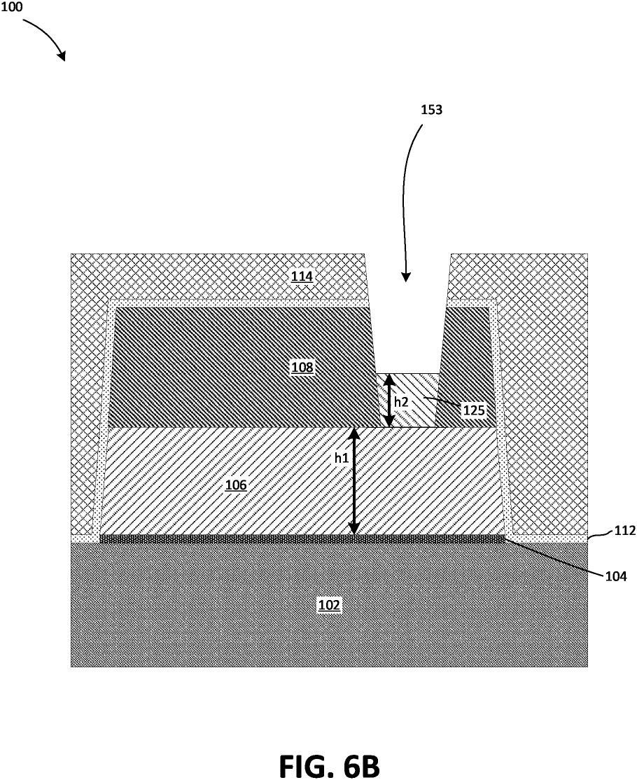

Referring now to FIG. 6A, this figure is a cross-sectional view of the interconnect structure of the semiconductor device 100 of FIG. 5A, after additional fabrication operations, according to embodiments. As shown in FIGS. 6A and 6B (a cross-sectional view of the interconnect structure of the semiconductor device 100 of FIG. 5B, after additional fabrication operations), the OPL layer 116 is removed by any suitable material removal process. Then, a via 125 is grown (e.g., by selective Ru via growth) in the opening 153 to a second height h2. In certain examples, the via 125 may be comprised of Ru, and may be the same material as that of the bulk metal layer 106. In other examples, the material of the via 125 may be different than that of the bulk metal layer 106, and may include one or more materials other than, or in addition to, Ru. The first height h1 of the bulk metal layer 106 is well-controlled because it is determined by the initial Ru deposition thickness (i.e., the first height h1). The via height h2 is also well controlled because it is determined by the selective growth process, which may be more accurate than a metal recess process in related techniques. That is, in related manufacturing processes that use a subtractive process to determine a via height, after a Ru etch the height of bulk metal layer 106 may have large variations and the height and/or shape of via 125 may also have large variations. However, according to the present embodiments, because the via height h2 is well controlled due to the selective growth process, the final dimensions (i.e., shape and height) and uniformity of the vias 125 may be improved.

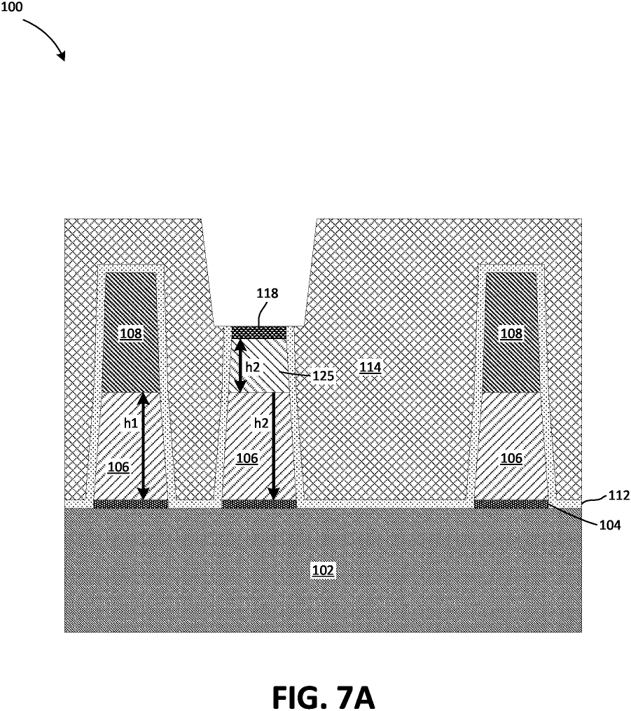

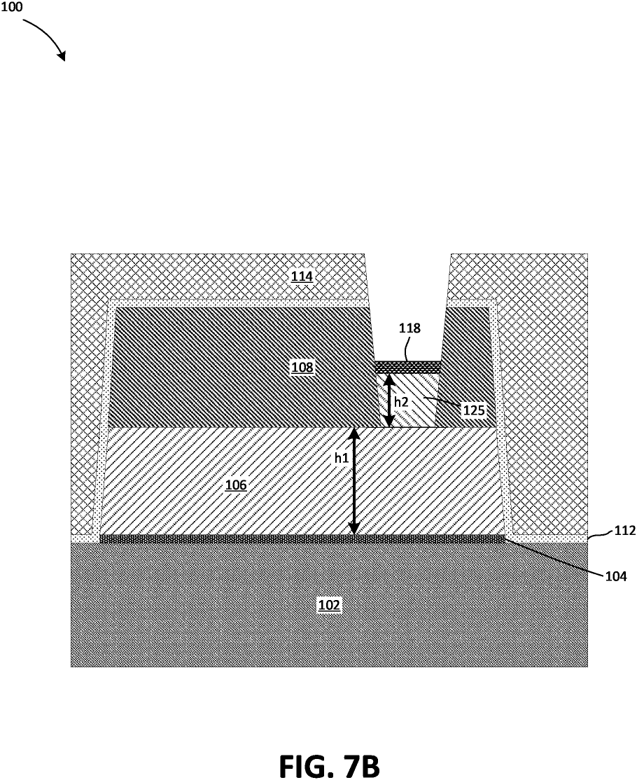

Referring now to FIGS. 7A and 7B, these figures are cross-sectional views of the interconnect structure of the semiconductor device 100 of FIGS. 6A and 6B respectively, after additional fabrication operations, according to embodiments. As shown in FIGS. 7A and 7B, in certain embodiments, an additional protective liner layer 118 may be grown by a selective growth process on a top surface of the via 125. In certain examples, the protective liner layer 118 may comprise on or more materials which are more compatible with a CMP process such as, for example, W, Ti, etc. It should be appreciated that in other embodiments, the protective liner layer 118 may be omitted.

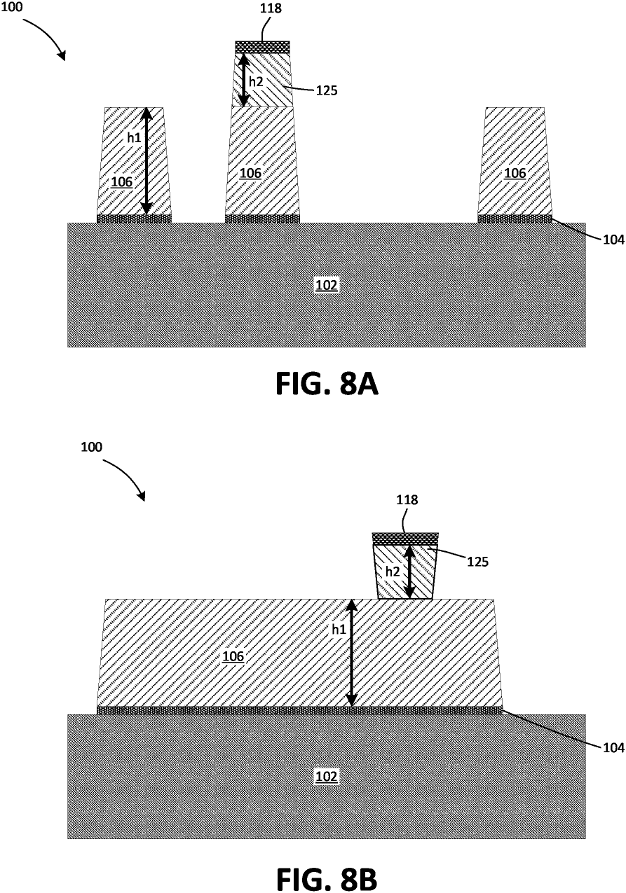

Referring now to FIGS. 8A and 8B, these figures are cross-sectional views of the interconnect structure of the semiconductor device 100 of FIGS. 7A and 7B respectively, after additional fabrication operations, according to embodiments. As shown in FIGS. 8A and 8B, several layers of the semiconductor device are removed by one or more suitable material removal processes. In particular, the sacrificial material layer 114, the liner layer 112 and the hardmask 108 are all removed in one or more processing steps. Thus, as shown in FIGS. 8A and 8B, the bulk metal layer 106 and the via 125 remain.

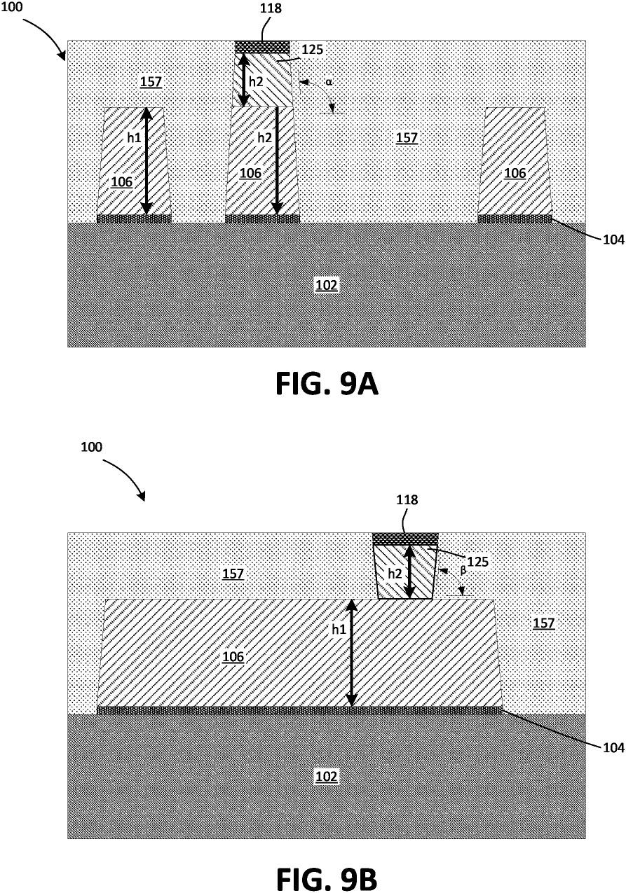

Referring now to FIGS. 9A and 9B, these figures are cross-sectional views of the interconnect structure of the semiconductor device 100 of FIGS. 8A and 8B respectively, after additional fabrication operations, according to embodiments. As shown in FIGS. 9A and 9B, an interlayer dielectric (ILD) layer 157 (e.g., a low-κ dielectric is formed on the semiconductor device 100, and a CMP removal process is used to planarize the top surface of the ILD layer 157 while using the protective liner layer 118 as a stopping point for the CMP removal process. As shown in FIG. 9A, the via 125 has a negative taper (or straight taper) above the bulk metal layer 106 (i.e., an angle α that is ≥ 90 degrees). In other words, the via 125 has a negative taper when viewed in cross-section along the X line of FIG. 1B. Moreover, it can be seen in FIG. 9B that the via 125 has a positive taper (i.e., it gets wider in a direction away from the underlying device 102 and has an angle β that is < 90 degrees) above the bulk metal layer 106 when viewed in cross-section along the Y line of FIG. 1B. As such, in certain embodiments, the taper angle of the via 125 is different (i.e., negative versus positive or straight versus positive) in the X and Y directions indicated in FIG. 1B. In the present embodiments, both the first height h1 of the bulk metal layer 106 and the second height h2 of the via 125 are well controlled due to the selective growth processes used (i.e., versus a subtractive patterning process for the via where the final height and shape of the vias may not be well controlled). Also, the shape and taper angle of the via 125 are well controlled and uniform.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of manufacturing an interconnect structure for a semiconductor device, the method comprising:
forming a metal interconnect layer on a substrate;
forming a hardmask on the metal interconnect layer;
patterning the metal interconnect layer and hardmask;
forming a sacrificial material layer to overfill the patterned metal interconnect layer and hardmask;
selectively removing a portion of the sacrificial layer and the hardmask to form a via opening; and
forming a via on the metal interconnect layer in the via opening by a selective metal growth process.

2. The method according to claim 1, further comprising completely removing the sacrificial material layer after the formation of the via.

3. The method according to claim 2, further comprising removing the hardmask.

4. The method according to claim 3, further comprising forming an interlayer dielectric layer to fill in areas between lines of the metal interconnect layer and the via.

5. The method according to claim 1, wherein the via has a positive taper angle in a first direction in a cross-sectional view, and the via has a negative taper angle in a second direction in the cross-sectional view that is orthogonal to the first direction.

6. The method according to claim 1, further comprising forming a metal liner layer between the metal interconnect layer and the substrate.

7. The method according to claim 1, further comprising, prior to forming the sacrificial material layer, forming a liner layer on sidewalls of the metal interconnect layer and sidewalls of the hardmask.

8. The method according to claim 1, wherein the via and the metal interconnect layer comprise Ru.

9. The method according to claim 1, wherein the via has a positive taper angle in a first direction in a cross-sectional view, and the via has a straight angle in a second direction in the cross-sectional view that is orthogonal to the first direction.

10. The method according to claim 1, further comprising forming a metal cap layer on an upper surface of the via.

11. An interconnect structure for a semiconductor device, the interconnect structure comprising:
a metal interconnect layer formed on a substrate;
a via formed on the metal interconnect layer by a selective metal growth process,
wherein the via has a positive taper angle or is vertical in a first direction in a cross-sectional view, and the via has a negative or vertical taper angle in a second direction in the cross-sectional view that is orthogonal to the first direction.

12. The interconnect structure according to claim 11, wherein the first direction is an along-metal line direction and the second direction is a cross-metal line direction.

13. The interconnect structure according to claim 11, further comprising an interlayer dielectric layer formed to fill in areas between lines of the metal interconnect layer and the via.

14. The interconnect structure according to claim 13, wherein the interlayer dielectric layer comprises a low-x dielectric material.

15. The interconnect structure according to claim 11, further comprising a metal liner layer formed between the metal interconnect layer and the substrate.

16. The interconnect structure according to claim 11, wherein the metal liner layer comprises TaN.

17. The interconnect structure according to claim 11, wherein the via and the metal interconnect layer comprise Ru.

18. The interconnect structure according to claim 11, wherein the via has a positive taper angle in the first direction, and the via has a straight angle in the second direction.

19. The interconnect structure according to claim 11, further comprising forming a metal cap layer on an upper surface of the via.

20. The interconnect structure according to claim 11, wherein the via and the metal interconnect layer are comprised of the same material.
